(19) United States
(12) Patent Application Publication
(10) Pub. No.: US 2023/0068337 A1
(43) Pub. Date: Mar. 2, 2023

(54) DISPLAY DEVICE

(71) Applicant: Samsung Display Co., Ltd., Yongin-si (KR)

(72) Inventors: CHIWOOK AN, Hwaseong-si (KR); Hyunduck Cho, Anyang-si (KR); Beohmrock Choi, Seoul (KR); Hyeonbum Lee, Hwaseong-si (KR); Jongbeom Hong, Yongin-si (KR)

(21) Appl. No.: 17/858,939

(22) Filed: Jul. 6, 2022

(30) Foreign Application Priority Data
Aug. 26, 2021 (KR) 10-2021-0113164

(51) Int. Cl. H01L 51/52; H01L 27/32; G06F 3/044

(52) U.S. Cl. CPC H01L 51/5284; H01L 27/323; H01L 27/322; H01L 27/3246; H01L 51/5253; G06F 3/0446

(57) ABSTRACT

A display device includes a display panel that includes a first region and a second region, each of that includes first to third light emitting regions and a non-light emitting region, and that includes first to third light emitting elements that provide different colors of light to corresponding first to third light emitting regions, at least one insulation layer disposed on the display panel, a light blocking pattern disposed on the insulation layer, and that overlaps the non-light emitting region, and a passivation layer that covers the light blocking pattern, wherein each of the first to third light emitting regions of the second region includes a plurality of unit regions, and each of the unit regions has the same width in one direction, and has a width smaller than the width of each of the first to third light emitting regions of the first region in the one direction.

### CROSS-REFERENCE TO RELATED APPLICATIONS

This application claims priority from and the benefit of Korean Patent Application No. 10-2021-0113164, filed on Aug. 26, 2021, which is hereby incorporated by reference for all purposes as if fully set forth herein.

### BACKGROUND

### Field

Embodiments of the invention relate generally to a display device and, more specifically, to a display device that may operate in two modes.

### Discussion of the Background

Electronic devices such as smart phones, tablet computers, laptop computers, automotive navigation system units, and smart televisions are being developed. Such electronic devices are provided with a display device in order to provide information to a user.

A user requires an image of quality that matches a usage situation. For example, a user requires a brighter image when outside a building where there is natural light. For example, a user requires an image with a narrow viewing angle when using an electronic device on which personal information is being viewed.

The above information disclosed in this Background section is only for understanding of the background of the inventive concepts, and, therefore, it may contain information that does not constitute prior art.

### SUMMARY

Devices constructed/methods according to illustrative implementations of the invention are capable of providing substantially the same image quality in a private viewing mode as compared to a normal viewing mode.

Inventive concepts consistent with one or more embodiments described hereinbelow provide for a display device that includes a display panel having the same color purity at a narrow viewing angle as compared to a wide viewing angle.

Additional features of the inventive concepts will be set forth in the description that follows, and in part will be apparent from the description, or may be learned by practice of the inventive concepts.

An embodiment provides a display device including a display panel that includes a first region and a second region, each of which includes first to third light emitting regions and a non-light emitting region, and that includes first to third light emitting elements that provide different colors of light to corresponding first to third light emitting regions, at least one insulation layer disposed on the display panel, a light blocking pattern disposed on the insulation layer, and that overlaps the non-light emitting region, and a passivation layer that covers the light blocking pattern, wherein each of the first to third light emitting regions of the second region includes a plurality of unit regions, and a first width of each of the unit regions in one direction is equal to each of the unit regions and a second width of each of the first to third light emitting regions of the first region in one direction is smaller than the first width.

In an embodiment, a number of the respective unit regions included in the first to third light emitting regions of the second region may be different from each other.

In an embodiment, the number of the unit regions may be proportional to area sizes of the first to third light emitting regions of the first region.

In an embodiment, among the first to third light emitting regions of each of the first and second regions, green light may be provided to the first light emitting region, red light may be provided to the second light emitting region, and blue light is provided to the third light emitting region, and in the second region, a number of the unit regions included in the third light emitting region may be the greatest, and in the second region, a number of the unit regions included in the first light emitting region may be the smallest.

In an embodiment, the first light emitting region of each of the first region and the second region may be provided in plurality.

In an embodiment, each of the first to third light emitting regions may include a plurality of sub-unit regions, and the respective sub-unit regions may have widths different from each other in the one direction.

In an embodiment, a number of the sub-unit regions included in the first light emitting region of the first region may be different from a number of the unit regions included in the first light emitting region of the second region, and a number of the sub-unit regions included in the second light emitting region of the first region may be different from a number of the unit regions included in the second light emitting region of the second region.

In an embodiment, each of the first to third light emitting elements may include a first electrode, a second electrode disposed on the first electrode, and a light emitting layer disposed between the first electrode and the second electrode, and the display panel may include a pixel definition layer including a plurality of openings that expose at least a portion of the first electrodes, wherein the respective areas of the openings may define the first to third light emitting regions.

In an embodiment, the pixel definition layer may include a first partitioning pattern overlapping the second region and disposed on the first electrodes exposed by the openings, and the unit regions of the second region may be defined by the areas of the openings partitioned by the first partitioning pattern.

In an embodiment, each of the first to third light emitting regions of the first region may include a plurality of sub-unit regions, the pixel definition layer may include a second partitioning pattern overlapping the first region and disposed on the first electrodes exposed by the openings, and the unit regions of the first region may be defined by the areas of the openings partitioned by the second partitioning pattern.

In an embodiment, the light blocking pattern may overlap the pixel definition layer except for the second partitioning pattern of the pixel definition layer.

In an embodiment, the display panel may further include a thin film encapsulation layer covering the first to third light emitting elements and including a plurality of inorganic layers and an organic layer disposed between the inorganic layers, and an input sensor disposed on the thin film encapsulation layer and including a plurality of sensing insulation layers and conductive layers disposed between the sensing insulation layers, wherein the insulation layer corresponds to a sensing insulation layer disposed on the uppermost portion of the sensing insulation layers.

In an embodiment, the display device may further include an optical member disposed on the passivation layer, and including at least one of a reflection prevention film, a polarizing film, or a gray filter.

In an embodiment, the display device may further include a light filter member disposed on the passivation layer, and including color filters that overlap corresponding first to third light emitting regions.

In an embodiment, each of the unit regions of the second region may have a donut shape, an outer diameter that defines the boundary of each of the unit regions may correspond to the width of each of the unit regions in one direction, and respective inner diameters of the unit regions included in different first to third light emitting regions of the second region may be different from each other.

In an embodiment, each of the unit regions of the second region may have a quadrangular shape that defines a boundary, and respective inner diameters of the unit regions included in different first to third light emitting regions of the second region may be different from each other.

In an embodiment, the display panel may activate the first to third light emitting elements of the first region and the first to third light emitting elements of the second region in a first operation mode, and may inactivate the first to third light emitting elements of the first region and activates the first to third light emitting elements of the second region in a second operation mode.

In an embodiment, a display device includes a display panel including a pixel definition layer on which openings defining a normal light emitting region and a private light emitting region spaced apart from the normal light emitting region are defined, and light emitting elements overlapping a corresponding normal light emitting region and a corresponding private light emitting region and configured to provide the same color of light, an insulation layer disposed on the display panel, a light blocking pattern disposed on the insulation layer, and a passivation layer covering the light blocking pattern, wherein each of the light emitting elements includes a first electrode, at least a portion of which is exposed by corresponding openings, a second electrode disposed on the first electrode, and a light emitting layer disposed between the first electrode and the second electrode, and the pixel definition layer includes a partitioning pattern disposed on the first electrode exposed by an opening overlapping the private light emitting region, and partitioning the private light emitting region into a plurality of unit regions.

In an embodiment, each of the unit regions may have the same width in one direction.

In an embodiment, the width of each of the unit regions may be smaller than a width of the normal light emitting region in the one direction.

In an embodiment, the light blocking pattern may overlap the partitioning pattern.

In an embodiment, the display panel may inactivate a light emitting element overlapping the normal light emitting region and activate a light emitting element overlapping the private light emitting region in a first operation mode, and may activate the light emitting element overlapping the normal light emitting region and the light emitting element overlapping the private light emitting region in a second operation mode.

In an embodiment, the unit regions may be defined by the areas of the openings partitioned by the partitioning pattern.

It is to be understood that both the foregoing general description and the following detailed description are illustrative and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate illustrative embodiments of the invention, and together with the description serve to explain the inventive concepts.

FIG. 1 is a perspective view of a display device according to an embodiment that is constructed according to principles of the invention.

FIG. 2 is an exploded perspective view of a display device according to an embodiment.

FIG. 3A is a cross-sectional view of a display module according to an embodiment.

FIG. 3B is a cross-sectional view of a display module according to an embodiment.

FIG. 4 is a plan view of a display panel according to an embodiment.

FIG. 5 is an equivalent circuit diagram of a pixel according to an embodiment.

FIG. 6 is a cross-sectional view of a display module according to an embodiment.

FIG. 7 is a plan view of an input sensing panel according to an embodiment.

FIG. 8 is a plan view illustrating an enlarged view of region TT′ of FIG. 7.

FIG. 9 is a plan view of an active region according to an embodiment.

FIG. 10 is a plan view of an enlarged view of one region of an active region according to an embodiment.

FIG. 11 is a cross-sectional view of a display module taken along I-I′ of FIG. 9.

FIG. 12 is a cross-sectional view of a display module taken along II-IF of FIG. 9.

FIG. 13 is a plan view of an active region according to an embodiment.

FIG. 14 is a cross-sectional view of a display module taken along of FIG. 13.

FIG. 15 is a plan view of a unit region according to an embodiment.

FIG. 16 is a plan view of a unit region according to an embodiment.

FIG. 17 is a plan view of a unit region according to an embodiment of the inventive concept.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing illustrative features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z—axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

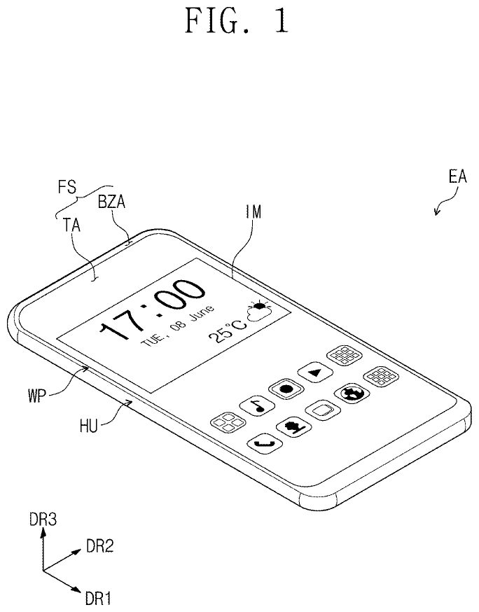

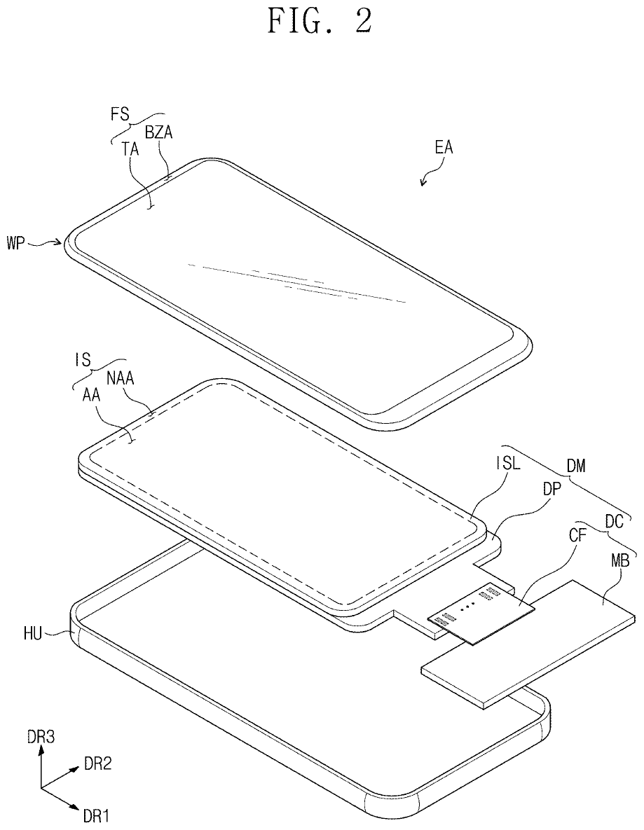

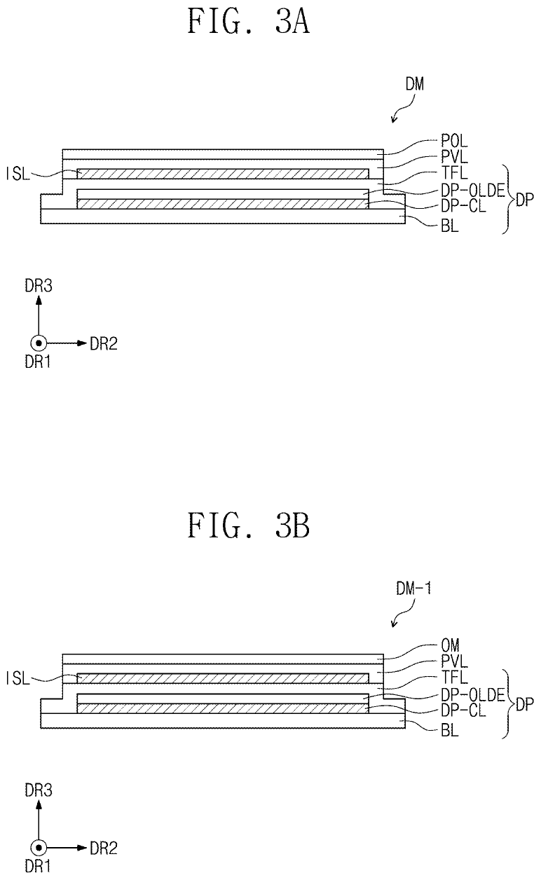

FIG. 1 is a perspective view of a display device according to an embodiment that is constructed according to principles of the invention. FIG. 2 is an exploded perspective view of a display device according to an embodiment. FIG. 3A is a cross-sectional view of a display module according to an embodiment. FIG. 3B is a cross-sectional view of a display module according to an embodiment.

Referring to FIG. 1 and FIG. 2, a display device EA may be a device activated by an electrical signal. The display device EA may include various embodiments. For example, the display device EA may be used in large display devices such as televisions, monitors, or external advertisement boards, and also in small and medium-sized display devices such as personal computers, notebook computers, personal digital terminals, car navigation system units, game machines, portable electronic apparatuses, and cameras.

It should be understood that these are merely illustrative of one example, and the display device EA may be employed in other display devices without departing from the inventive concept. In the embodiments described hereinbelow, the display device EA is illustrated as a smart phone.

The display device EA may display an image IM toward a third direction DR3 on a display surface FS parallel to each of a first direction DR1 and a second direction DR2. The image IM may include both a moving image and a still image. In FIG. 1, as an example of the image IM, a watch window and icons are illustrated. The display surface FS on which the image IM is displayed may correspond to a front surface of the display device EA, and may correspond to a front surface of a window panel WP.

In the embodiment, a front surface (or an upper surface) and a back surface (or a lower surface) of each member are defined on the basis of a direction in which the image IM is displayed. The front surface and the back surface oppose each other in a third direction DR3 and the normal direction of each of the front surface and the back surface may be parallel to the third direction DR3. Directions indicated by the first to third directions DR1, DR2, and DR3 are a relative concept, and may be converted to different directions. In the present disclosure, “on a plane” may mean when viewed in the third direction DR3.

The display device EA may include a window WP, a display module DM, and a housing HU. In the embodiment, the window panel WP and the housing HU may be bonded to each other to constitute the appearance of the display device EA.

The window panel WP may include an optically transparent insulation material. For example, the window panel WP may include glass or plastic. The window panel WP may have a multi-layered structure or a single-layered structure. For example, the window panel WP may include a plurality of plastic films bonded with an adhesive, or a glass substrate and a plastic film bonded to each other with an adhesive.

A front surface of the window panel WP may define the front surface of the display device EA as described above. The transmissive region TA may be an optically transparent region. For example, the transmissive region TA may be a region having a visible light transmittance of about 90% or higher.

A bezel region BZA may be a region having a relatively low light transmittance compared to the transmissive region TA. The bezel region BZA may define the shape of the transmissive region TA. The bezel region BZA may be adjacent to the transmissive region TA, and may surround the transmissive region TA.

The bezel region BZA may have a predetermined color. The bezel region BZA may cover a peripheral region NAA of the display module DM to block the peripheral region NAA from being viewed from the outside. This is only illustrated as one possible implementation, and in the window panel WP according to an embodiment, the bezel region BZA may be omitted.

The display module DM may display the image IM and may sense an external input. The display module DM may include an entire surface IS including an active region AA and the peripheral region NAA. The active region AA may be a region activated by an electrical signal.

In the embodiment, the active region AA may be a region in which the image IM is displayed, and at the same time, may be a region in which an external input is sensed. The transmissive region TA may overlap at least a portion of the active region AA. For example, the transmissive region TA may overlap the entire=surface or at least a portion of the active region AA.

Accordingly, a user may visually recognize the image IM through the transmissive region TA, or may provide an external input. However, this is only illustrative as one possible implementation. In the display module DM according to an embodiment, a region in which the image IM is displayed and a region in which an external input is sensed may be separated from each other in the active region AA.

The peripheral region NAA may be a region covered by the bezel region BZA. The peripheral region NAA may be adjacent to the active region AA. The peripheral region NAA may surround the active region AA. In the peripheral region NAA, a driving circuit or a driving line for driving the active region AA may be disposed.

in the embodiment, the display module DM may include the display panel DP, an input sensor ISL, and a driving circuit DC.

The display panel DP may be a component that substantially generates the image IM. The image IM generated by the display panel DP may be visually recognized by a user from the outside through the transmissive region TA.

The input sensor ISL may sense an external input applied from the outside. As described above, the input sensor ISL may sense an external input provided to the window panel WP.

The external input may include various forms of inputs provided from the outside of the display device EA. The external input applied from the outside may be provided in various forms. For example, the external input may include not only a contact by a part of a user's body, such as a hand, but also an external input (e.g., hovering) applied in close proximity, or adjacent to the display device EA at a predetermined distance. Also, the external input may have various forms such as force, pressure, and light, but is not limited to any one embodiment.

The driving circuit DC may be electrically connected to the display panel DP and the input sensor ISL. The driving circuit unit DC may include a main circuit board MB and a flexible circuit board CF.

The flexible circuit board CF may be electrically connected to the display panel DP. The flexible circuit board CF may connect the display panel DP and the main circuit board MB. However, this is illustrated as one possible implementation. The flexible circuit board CF according to one or more embodiments may not be connected to the main circuit board MB, and the flexible circuit board CF may be a rigid board.

The flexible circuit board CF may be connected to pads (display pads) of the display panel DP disposed in the peripheral region NAA. The flexible circuit board CF may provide an electrical signal for driving the display panel DP to the display panel DP. The electrical signal may be generated in the flexible circuit board CF or in the main circuit board MB.

The main circuit board MB may include various driving circuits for driving the display module DM or connectors for supplying power. The main circuit board MB may be connected to the display module DM through the flexible circuit board CF.

The display module DM according to an embodiment may be easily controlled through one main circuit board MB. However, this is only illustrative as one possible implementation. In the display module DM according to an embodiment, the display panel DP and the input sensor ISL may be connected to different main circuit boards in other possible implementations.

The housing HU may be bonded to the window panel WP. The housing HU may be bonded to the window panel WP to provide a predetermined internal space. The display module DM may be received in the internal space.

The housing HU may include a material having relatively high rigidity. For example, the housing HU may include glass, plastic, or a metal, or may include a plurality of frames and/or plates composed of a combination thereof. The housing HU may stably protect the components of the display device EA received in the internal space from an external impact.

The display device EA according to an embodiment may be a foldable display device EA that is folded on the basis of a virtual axis extended in a predetermined direction, or a rollable display device EA that is rolled on the basis of a virtual axis extended in a predetermined direction, but is not limited to any one thereof.

Referring to FIG. 3A, in the embodiment, the display module DM may include the display panel DP, the input sensor ISL, a light blocking layer PVL, and an optical member POL.

The display panel DP may include a base layer BL, a circuit element layer DP-CL, a display element layer DP-OLED, and a thin film encapsulation layer TFL.

The display panel layer DP may include a plurality of insulation layers, a semiconductor pattern, a conductive pattern, a signal line, and the like. The insulation layer, the semiconductor layer, and the conductive layer are formed by coating, deposition, and the like. Thereafter, the insulation layer, the semiconductor layer, and the conductive layer may be selectively patterned by photolithography and etching. The semiconductor pattern, the conductive pattern, the signal line, and the like included in circuit element layer DP-CL and the display element layer DP-OLED are formed in the above manner.

The base layer BL may be a base layer on which the circuit element layer DP-CL, the display element layer DP-OLED, the thin film encapsulation layer TFL, and the input sensor ISL may be stacked. The base layer BL may be flexible or rigid, and may be provided as a single layer or may have a multi-layered structure, but is not limited to any one thereof.

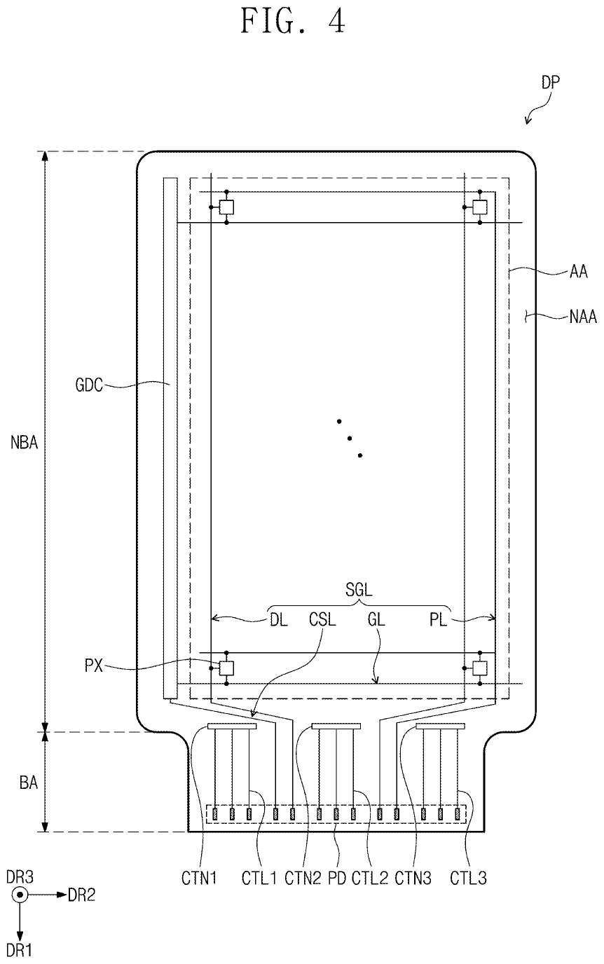

The circuit element layer DP-CL may be disposed on the base layer BL. The circuit element layer DP-CL may include a plurality of insulation layers, a plurality of conductive layers, and a semiconductor layer. The plurality of conductive layers of the circuit element layer DP-CL may constitute signal lines or a control circuit of a pixel PX (see FIG. 4).

The display element layer DP-OLED may be disposed on the circuit element layer DP-CL. The display element layer DP-OLED may include organic light emitting elements. However, this is only illustrative as one possible implementation. The display element layer DP-OLED according to an embodiment may include inorganic light emitting elements, organic-inorganic light emitting elements, or a liquid crystal layer.

The thin film encapsulation layer TFL may include an organic layer and a plurality of inorganic layers that seal the organic layer. The thin film encapsulation layer TFL may seal the display element layer DP-OLED to block moisture and oxygen introduced to the display element layer DP-OLED.

The input sensor ISL is disposed on the thin film encapsulation layer TFL. The input sensor ISL may be formed on the thin film encapsulation layer TFL through a continuous process. In this case, the input sensor ISL may be described as being ‘directly disposed’ on the display panel DP. Being directly disposed may mean that a third element is not disposed between the input sensor ISL and the display panel DP. That is, a separate adhesive member may not be disposed between the input sensor ISL and the display panel DP.

The input sensor ISL may sense an external input by any one of a self-capacitance type method or a mutual capacitance type method. Sensing patterns included in the input sensor ISL may be variously changed in correspondence to a method to be disposed and connected.

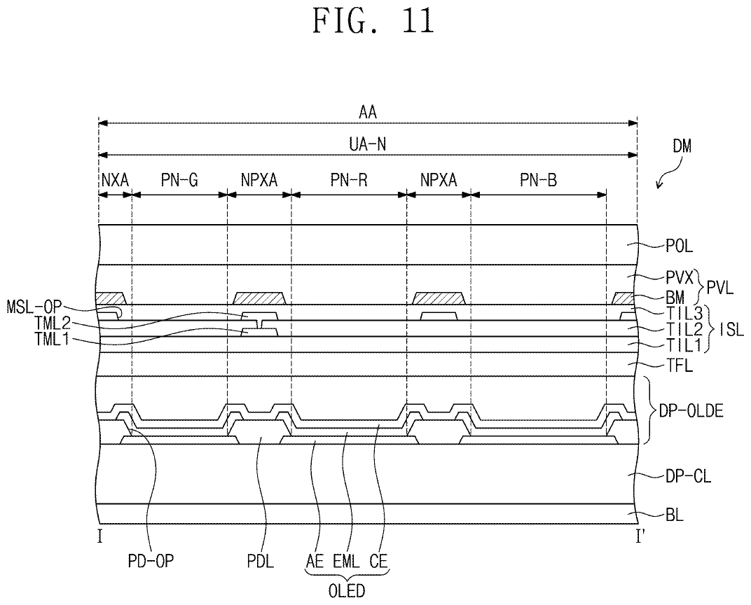

The light blocking layer PVL is disposed on the input sensor ISL. The light blocking layer PVL may include a light blocking pattern BM and a passivation layer PVX (see FIG. 11) that covers the light blocking pattern BM (see FIG. 11), both of which will be described later. The light blocking layer PVL may be disposed on one region that emits light when the display device EA operates in a private mode (hereinafter, a first operation mode) to serve to prevent color mixing of light emitted at a narrow viewing angle.

The optical member POL may be disposed on the light blocking layer PVL to reduce the external light reflectance of the display module DM with respect to light incident on the display panel DP. For example, the optical member POL may include at least one of a reflection prevention film, a polarizing film, or a gray filter.

Referring to FIG. 3B, in the embodiment, a display module DM-1 may include a display panel DP, an input sensor ISL, a light blocking layer PVL, and a light filter member OM. Descriptions of the display panel DP, the input sensor ISL, and the light blocking layer PVL may correspond to those of the display panel DP, the input sensor ISL, and the light blocking layer PVL of the display module DM given with reference to FIG. 3A, and redundant descriptions thereof will be omitted.

In the embodiment, the display module DM-1 may include the light filter member OM. The light filter member OM may be disposed on the light blocking layer PVL.

The light filter member OM may selectively transmit light provided from the display panel DP. The light filter member OM may include a plurality of color filters and a light blocking pattern disposed between the color filters.

The color filters may selectively transmit corresponding light among red light, green light, and blue light. At this time, each of the color filters may include a polymer photosensitive resin and a pigment or dye. [0104] In addition, the light filter member OM may further include a planarization layer disposed on the color filters.

The planarization layer is disposed on the color filters to cover irregularities generated during a forming process of the color filters. Accordingly, components disposed on the light filter member OM may be stably bonded to the light filter member OM.

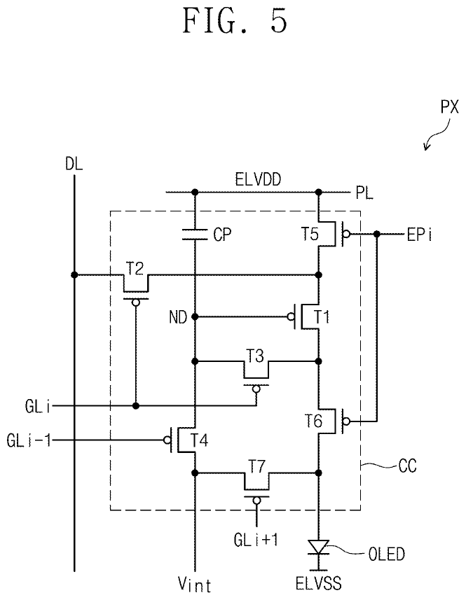

FIG. 4 is a plan view of a display panel according to an embodiment. FIG. 5 is an equivalent circuit diagram of a pixel according to an embodiment.

Referring to FIG. 4, the display panel DP may be divided into an active region AA and a peripheral region NAA. The active region AA of the display panel DP may be a region in which an image is displayed, and the peripheral region NAA may be a region in which a driving circuit, a driving wire and the like are disposed. In the active region AA, light emitting elements of each of a plurality of pixels PX may be disposed. The active region AA may overlap at least a portion of the transmissive region TA, and the peripheral region NAA may be covered by the bezel region BZA.

The display panel DP may include a driving circuit GDC, a plurality of signal lines SGL (hereinafter, signal lines), the plurality of panels PX (hereinafter, pixels) a plurality of lower contact holes CTN1, CTN2, and CTN3, a plurality of contact lines CTL1, CTL2, and CTL3, and a plurality of pads PD connected to a corresponding contact line.

Each of the pixels PX may include a light emitting element and a plurality of transistors connected thereto. The pixels PC may emit light in correspondence to an applied electrical signal.

The signal lines SGL include scan lines GL, data lines DL, a power line PL, and a control signal line CSL. Each of the scan lines GL may be connected to a corresponding pixel PX among the pixels PX. Each of the data lines DL may be connected to a corresponding pixel PX among the pixels PX. The power line PL may be connected to the pixels PX and provide a power voltage. The control signal line CSL may provide control signals to a scan driving circuit.

The driving circuit GDC may be disposed in the peripheral region NAA. The driving circuit GDC may include the scan driving circuit. The scan driving circuit generates scan signals, and may sequentially output the scan signals to the scan lines GL. The scan driving circuit may further output another control signal to a driving circuit of the pixels PX.

The scan driving circuit may include a plurality of thin film transistors formed through the same process as that of the driving circuit of the pixels PX, for example, a low temperature polycrystalline silicon (LTPS) process or a low temperature polycrystalline oxide (LTPO) process.

The display panel DP according to an embodiment may include a bending region BA and a non-bending region NBA adjacent to the bending region BA. The bending region BA in the display panel DP may be a region to which the flexible circuit board CF described with reference to FIG. 2 is bonded and that is bent toward a back surface of the display panel DP. Thus, the flexible circuit board CF and the main circuit board MB may be disposed on the back surface of the display panel DP while being bonded to the bending region BA of the display panel DP. The data lines DL and the signal lines SGL may be extended from the non-bending region NBA to the bending region BA and be connected to corresponding pads PD.

In an embodiment, a width in the second direction DR2 of the display panel DP may be greater in the non-bending region NBA than in the bending region BA.

The display panel DP may include the contact holes CTN1, CTN2, and CTN3 defined in the peripheral region NAA. The lower contact holes CTN1, CTN2, and CTN3 may overlap upper contact holes CTN-1, CTN-2, and CTN-3 of the input sensor ISL to be described later.

The contact lines CTL1, CTL2, and CTL3 may be extended from the lower contact holes CTN1, CTN2, and CTN3 to the bending region BA and be connected to corresponding pad PD.

One end of each of first contact lines CTL1 is extended from a corresponding first lower contact hole CTN1, and the first contact lines CTL1 may be connected to a pad PD corresponding to the other end each thereof.

One end of each of second contact lines CTL2 is extended from a corresponding second lower contact hole CTN2, and the second contact lines CTL2 may be connected to a pad PD corresponding to the other end each thereof.

One end of each of third contact lines CTL3 is extended from a corresponding third lower contact hole CTN3, and the third contact lines CTL3 may be connected to a pad PD corresponding to the other end each thereof.

FIG. 4 illustrates three lower contact holes CTN1, CTN2, and CTN3, but this illustrates an example of the arrangement relationship of the lower contact holes. As long as lower contact holes overlap upper contact holes of the input sensor ISL, the arrangement relationship and the number of the lower contact holes are not limited to any one embodiment.

Referring to FIG. 5, an enlarged signal circuit diagram of one pixel PX among the plurality of pixels is illustrated. FIG. 5 illustrates the pixel PX connected to an i-th scan line GLi and an i-th light emission control line EPi.

The pixel PX may include a light emitting element OLED and a pixel circuit CC. The pixel circuit CC may include a plurality of transistors T1 to T7 and a capacitor CP. The plurality of transistors T1 to T7 may be formed through a low temperature polycrystalline silicon (LTPS) process or a low temperature polycrystalline oxide (LTPO) process.

The pixel circuit CC controls the amount of current flowing through the light emitting element OLED in correspondence to a data signal. The light emitting element OLED may emit light to a predetermined luminance in correspondence to an amount of current provided from the pixel circuit CC. To this end, the level of a first power ELVDD may be set to be higher than the level of a second power ELVSS. The light emitting element OLED may include an organic light emitting element or a quantum dot light emitting element.

Each of the plurality of transistors T1 to T7 may include an input electrode (or a source electrode), an output electrode (or a drain electrode), and a control electrode (or a gate electrode). In the present disclosure, any one of the input electrode and the output electrode may be referred to as a first electrode, and the other one thereof may be referred to as a second electrode for convenience.

The first electrode of a first transistor T1 is connected to the first power ELVDD via a fifth transistor T5, and the second electrode of the first transistor T1 is connected to an anode (first electrode) of the light emitting element OLED via a sixth transistor T6. The first transistor T1 may be referred to as a driving transistor in the present disclosure.

The first transistor T1 controls the amount of current flowing through the light emitting element OLED in correspondence to a voltage applied to the control electrode of the first transistor T1.

A second transistor T2 is connected between a data line DL and the first electrode of the first transistor T1. In addition, the control electrode of the second transistor T2 is connected to the i-th scan line GLi. The second transistor T2 is turned on when an i-th scan signal is provided to the i-th scan line GLi, and electrically connects the data line DL and the first electrode of the first transistor T1.

A third transistor T3 is connected between the second electrode of the first transistor T1 and the control electrode of the first transistor T1. The control electrode of the third transistor T3 is connected to the i-th scan line GLi. The third transistor T3 is turned on when the i-th scan signal is provided to the i-th scan line GLi, and electrically connects the second electrode of the first transistor T1 and the control electrode of the first transistor T1. Accordingly, when the third transistor T3 is turned on, the first transistor T1 is connected in the form of a diode.

A fourth transistor T4 is connected between a node ND and an initialization power generating unit. In addition, the control electrode of the fourth transistor T4 is connected to an i-1-th scan line GLi-1. The fourth transistor T4 is turned on when an i-1-th scan signal is provided to the i-1-th scan line GLi-1, and provides an initialization voltage Vint to the node ND.

The fifth transistor T5 is connected between the power line PL and the first electrode of the first transistor T1. The control electrode of the fifth transistor T5 is connected to the i-th light emission control line EPi.

The sixth transistor T6 is connected between the second electrode of the first transistor T1 and the anode (first electrode) of the light emitting element OLED. In addition, the control electrode of the sixth transistor T6 is connected to the i-th light emission control line EPi.

A seventh transistor T7 is connected between the initialization power generating unit and the anode of the light emitting element OLED. In addition, the control electrode of the seventh transistor T7 is connected to an i+1-th scan line GLi+1. The seventh transistor T7 is turned on when an i+1-th scan signal is provided to the i+1-th scan line GLi+1, and provides the initialization voltage Vint to the anode of the light emitting element OLED.

The seventh transistor T7 may improve black expression capability of the pixel PX. Specifically, when the seventh transistor T7 is turned on, a parasitic capacitor of the light emitting element OLED is discharged. Then, when black luminance is implemented, the light emitting element OLED does not emit light due to a leakage current from the first transistor T1, and accordingly, the black expression capability may be improved.

Additionally, FIG. 5 illustrates the control electrode of the seventh transistor T7 being connected to the i+1-th scan line GLi+1, but the embodiment is not limited thereto. In another embodiment, the control electrode of the seventh transistor T7 may be connected to the i-th scan line GLi or the i-1-th scan line GLi-1.

The capacitor CP is disposed between the power line PL and the node ND. The capacitor CP stores a voltage corresponding to a data signal. When the fifth transistor T5 and the sixth transistor T6 are turned on in accordance to the voltage stored in the capacitor CP, the amount of current flowing in the first transistor T1 may be determined.

In the present invention, an equivalent circuit of the pixel PX is not limited to the equivalent circuit illustrated in FIG. 5. In another embodiment, the pixel PX may be implemented in various forms to allow the light emitting element OLED to emit light. Although FIG. 5 is illustrated based on a PMOS, the embodiment is not limited thereto. In another embodiment, the pixel circuit CC may be composed of an NMOS. In yet another embodiment, the pixel circuit CC may be composed of a combination of an NMOS and a PMOS.

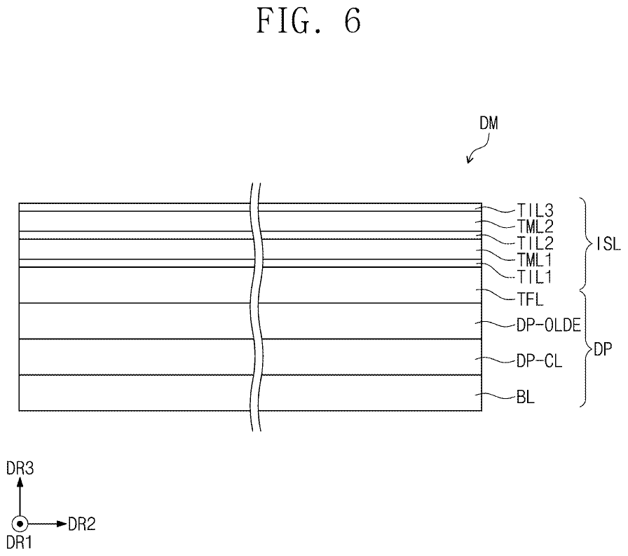

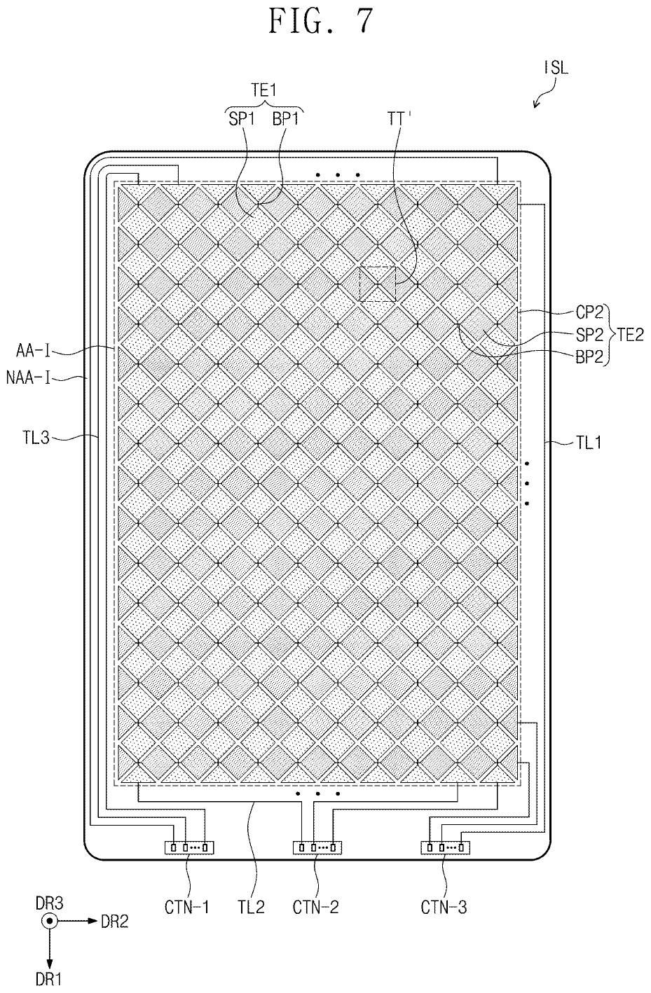

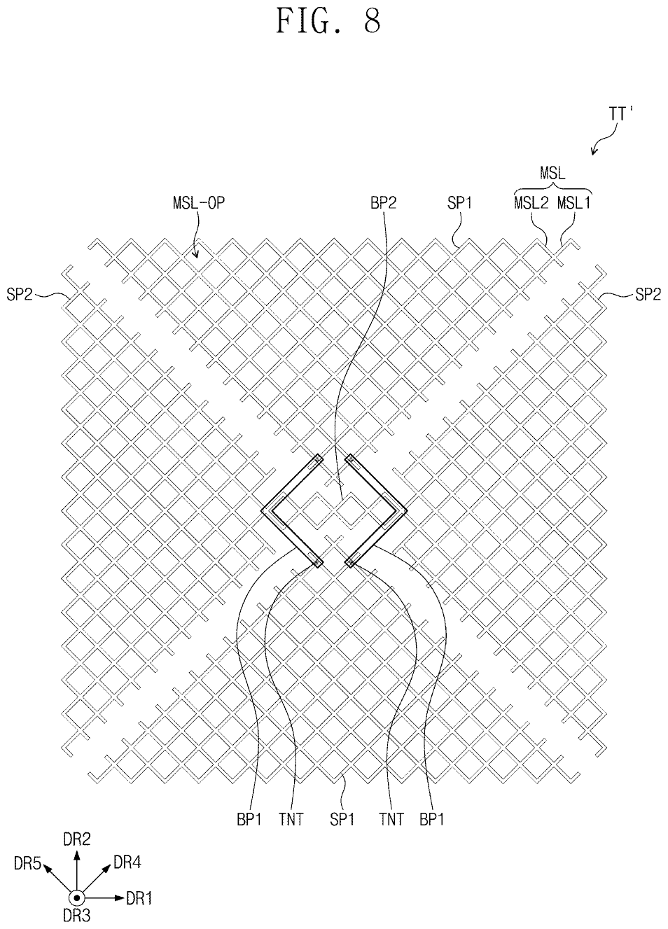

FIG. 6 is a cross-sectional view of a display module according to an embodiment. FIG. 7 is a plan view of an input sensing panel according to an embodiment. FIG. 8 is a plan view illustrating an enlarged view of region TT′ of FIG. 7. [0138] The input sensor ISL of the display module DM may be directly disposed on the display panel DP. Among the components of the display modules DM and DM-1 described with reference to FIG. 3A and FIG. 3B, components disposed on the input sensor ISL are omitted, and the staking structure of the input sensor ISL will be described.

The input sensor ISL may include a first sensing insulation layer TILL a first conductive layer TML1, a second sensing insulation layer TIL2, a second conductive layer TML2, and a third sensing insulation layer TIL3. The first sensing insulation layer TIL1 of the input sensor ISL may be directly disposed on the thin film encapsulation layer TFL. According to an embodiment of the input sensor ISL, the first sensing insulation layer TIL1 may be omitted.

Each of the first conductive layer TML1 and the second conductive layer TML2 may have a single-layered structure, or a multi-layered structure. A conductive layer of a multi-layered structure may include at least two of a transparent conductive layer and a metal layer. The conductive layer of a multi-layered structure may include metal layers including different metals from each other.

The first conductive layer TML1 and the second conductive layer TML2 may include, as a transparent conductive layer, at least one of indium tin oxide (ITO), indium zinc oxide (IZO), zinc oxide (ZnO), indium tin zinc oxide (ITZO), PEDOT, a metal nanowire, or graphene. The first conductive layer TML1 and the second conductive layer TML2 may include, as a metal layer, molybdenum, silver, titanium, copper, aluminum, or an alloy thereof.

For example, each of the first conductive layer TML1 and the second conductive layer TML2 may have a three-layered structure composed of titanium/aluminum/titanium. A metal having relatively high durability and low reflectance may be applied to an outer layer of a conductive layer, and a metal having high electrical conductivity may be applied to an inner layer of the conductive layer.

Each of the first sensing insulation layer TIL1 to the third sensing insulation layer TIL3 may include an inorganic film or an organic film. In the embodiment, each of the first sensing insulation layer TIL1 and the second sensing insulation layer TIL2 may include an inorganic film. The inorganic film may include at least one of an aluminum oxide, a titanium oxide, a silicon oxide, a silicon oxynitride, a zirconium oxide, or a hafnium oxide.

The third sensing insulation layer TIL3 may include an organic film. The organic film may include at least one of an acrylic resin, a methacrylic resin, polyisoprene, a vinyl-based resin, an epoxy-based resin, a urethane-based resin, a cellulose-based resin, a siloxane-based resin, a polyimide-based resin, a polyamide-based resin, or a perylene-based resin.

The third sensing insulation layer TIL3 may be a component corresponding to the ‘insulation layer’ set forth in the claims.

The input sensor ISL according to one or more embodiments may further includes a high dielectric constant layer disposed on the second conductive layer TML2 and covered by the third sensing insulation layer TIL3. The high dielectric constant layer may be a layer having a dielectric constant higher than the dielectric constant of the third sensing insulation layer TIL3. A detailed description will be followed.

Referring to FIG. 7, in the embodiment, the input sensor ISL may include a plurality of sensing electrodes TE1 and TE2 and a plurality of sensing lines TL1, TL2, and TL3.

The input sensor ISL may be divided into an active region AA-I and a peripheral region NAA-I adjacent to the active region AA-I. The active region AA-I and the peripheral region NAA-I of the input sensor ISL may correspond to the active region AA and the peripheral region NAA of the display panel DP.

The plurality of sensing electrodes TE1 and TE2 may include a first sensing electrode TE1 and a second sensing electrode TE2.

The first sensing electrode TE1 may be extended in the first direction DR1, and may be provided in plurality to be arranged along the second direction DR2. The first sensing electrode TE1 may include first sensing patterns SP1 and first conductive patterns BP1. The first sensing patterns SP1 may be arranged along the first direction DR1. At least one first conductive pattern BP1 may be connected to two first sensing patterns SP1 adjacent to each other.

The second sensing electrode TE2 may be extended in the second direction DR2, and may be provided in plurality to be arranged along the first direction DR1. The second sensing electrode TE2 may include second sensing patterns SP2 and second conductive patterns BP2. The second sensing patterns SP2 and the second conductive patterns BP2 are patterns having a single body shape patterned by the same process, but for convenience of description, the second sensing patterns SP2 and the second conductive patterns BP2 will be described separately.

The second sensing patterns SP2 may be arranged along the second direction DR2. At least one second conductive pattern BP2 may be disposed between two second sensing patterns SP2 adjacent to each other.

The sensing lines TL1, TL2, and T3 may include a first sensing line TL1, a second sensing line TL2, and a third sensing line TL3.

The input sensor ISL according to an embodiment may include a plurality of upper contact holes CTN-1, CTN-2, and CTN-3 defined in the peripheral region NAA. The upper contact holes CTN-1, CTN-2 and CTN-3 may be formed by penetrating the first sensing insulation layer TIL1 and the second sensing insulation layer TIL2. The upper contact holes CTN-1, CTN-2 and CTN-3 may respectively overlap corresponding lower contact holes CTN1, CTN2, and CTN3.

One end of the first sensing line TL1 may be connected to the second sensing electrode TE2, and the other end of the first sensing line TL1 may be extended to a third upper contact hole CTN-3. The other end of the first sensing line TL1 may be connected to the third contact line CTL3 (see FIG. 4) through the third lower contact hole CTN3 (see FIG. 4) and the third upper contact hole CTN-3 overlapping each other.

One end of the second sensing line TL2 may be connected to one end of the first sensing electrode TE1 and the other end of the second sensing line TL1 may be extended to a second upper contact hole CTN-2. The other end of the second sensing line TL2 may be connected to the second contact line CTL2 (see FIG. 4) through the second lower contact hole CTN2 (see FIG. 4) and the second upper contact hole CTN-2 overlapping each other.

One end of the third sensing line TL3 may be connected to the other end of the first sensing electrode TE1 and the other end of the third sensing line TL1 may be extended to a first upper contact hole CTN-1. The other end of the third sensing line TL3 may be connected to the first contact line CTL1 (see FIG. 4) through the first lower contact hole CTN1 (see FIG. 4) and the first upper contact hole CTN-1 overlapping each other.

The first sensing electrode TE1 according to an embodiment may be connected to the second sensing line TL2 and the third sensing line TL3. Accordingly, sensitivity according to a region may be uniformly maintained with respect to the first sensing electrode TE1, which is relatively long compared to the second sensing electrode TE2.

The contact lines CTL1, CTL2, and CTL3 may be connected to corresponding pads PD, and thus, connected to pads of the flexible circuit board CF. Thus, the sensing electrodes TE1 and TE2 may be electrically connected to the flexible circuit board CF and the main circuit board MB connected to the bending region BA of the display panel DP.

However, the embodiment is not limited thereto. The first sensing electrode TE1 may have a sensing line connected to either one end or the other end thereof, and at this time, any one of the first and second upper contact holes CTN-1 and CTN-2 may be omitted.

FIG. 8 illustrates the arrangement relationship of the first sensing patterns SP1, the first conductive patterns BP1, the second sensing patterns SP2, and the second conductive patterns BP2 in a plan view.

In the embodiment, the first sensing patterns SP1 and the second sensing electrode TE2 may include a mesh line MSL. The mesh line MSL may include a first mesh line MSL1 extended in a fourth direction DR4 and a second mesh line MSL2 extended in a fifth direction DR5.

The mesh lines MSL1 and MSL2 do not overlap light emitting regions to be described later, and overlap a non-light emitting region. The line width of the mesh lines MSL1 and MSL2 may be from several micrometers to several nanometers. The mesh lines MSL1 and MSL2 define a plurality of mesh openings MSL-OP. The mesh openings MSL-OP may correspond to corresponding light emitting regions among the light emitting regions to be described later in a one-to-one correspondence.

In the embodiment, the first sensing pattern SP1 and the second sensing electrode TE2 may constitute the second conductive layer TML2 described with reference to FIG. 6.

The first sensing patterns SP1 may be connected to a corresponding first conductive pattern BP1 through a sensing contact hole TNT defined on the second sensing insulation layer TIL2. Thus, even when disposed on the same layer as the second sensing electrode TE2, the first sensing patterns SP1 may be disposed insulated from the second sensing electrode TE2 through the first conductive pattern BP1 disposed on the first sensing insulation layer TIL1. Thus, the first conductive pattern BP1 and the second conductive pattern BP2 disposed on different layers may overlap each other on a plane.

A portion of each of the sensing lines TL1, TL2, and TL3 may be included in the first conductive layer TML1, and the remaining portions thereof may be included in the second conductive layer TML2. Lines disposed on different layers may be connected to each other through a contact hole defined on the second sensing insulation layer TIL2. However, the embodiment is not limited thereto. The sensing lines TL1, TL2, and TL3 may be included in only one layer between the first conductive layer TML1 and the second conductive layer TML2.

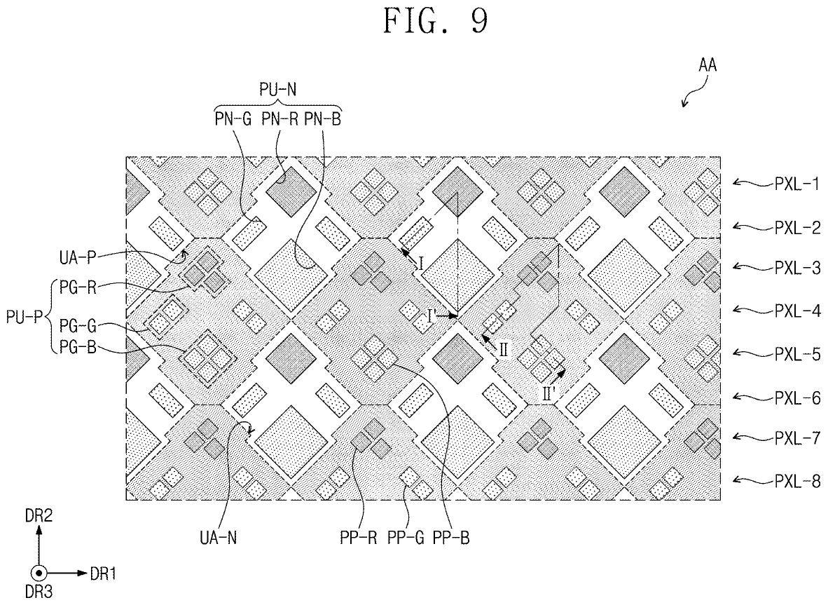

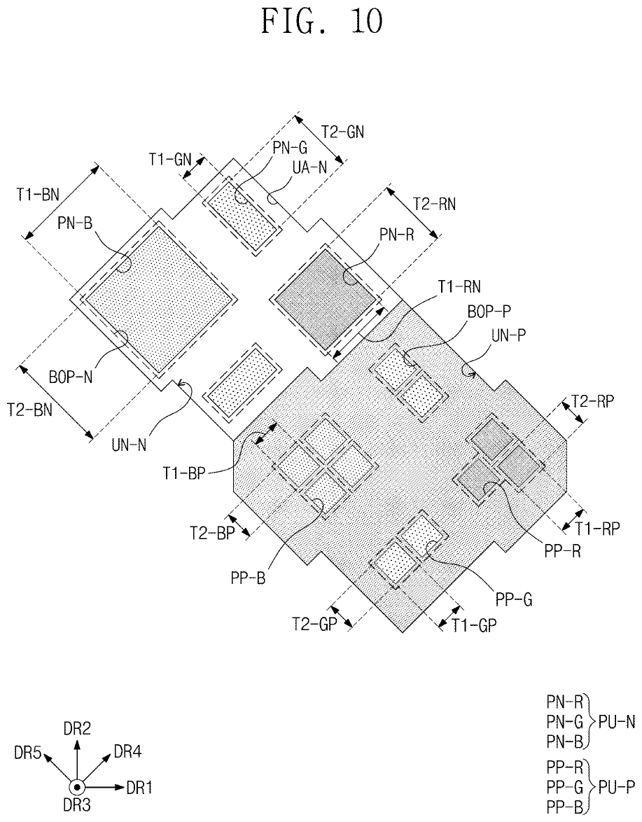

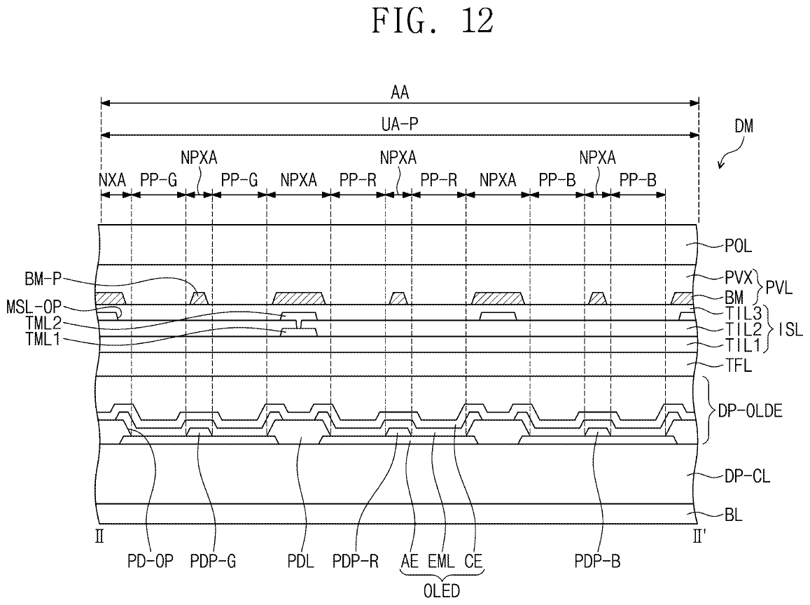

FIG. 9 is a plan view of an active region according to an embodiment. FIG. 10 is a plan view of an enlarged view of one region of an active region according to an embodiment. FIG. 11 is a cross-sectional view of a display module taken along I-I′ of FIG. 9. FIG. 12 is a cross-sectional view of a display module taken along II-IF of FIG. 9.

Referring to FIG. 9, the active region AA of the display panel DP (see FIG. 4) according to an embodiment may include a first region UA-N and a second region UA-P. The first region UA-N and the second region UA-P may include a plurality of light emitting regions that provide different colors of light.

The plurality of light emitting regions may define a plurality of pixel rows PXL-1 to PXL-8 extended in the second direction DR2. The plurality of pixel rows PXL-1 to PXL-8 are arranged in the first direction DR1.

For example, the first region UA-N may include a plurality of first to third light emitting regions PN-G, PN-R, and PN-B. In an embodiment, the first light emitting region PN-G that has the smallest area among the first to third light emitting regions PN-G, PN-R, and PN-B may be provided in plurality in the first region UA-N.

Two first light emitting regions may be spaced apart along the first direction DR1, and a second light emitting region PN-R and a third light emitting region PN-B may be spaced apart along the second direction DR2. The second light emitting region PN-R and the third light emitting region PN-B may be spaced apart from the first light emitting region PN-G in directions crossing the first direction DR1 and the second direction DR2, respectively.

The second region UA-P may include a plurality of first to third light emitting regions PG-G, PG-R, and PG-B. In an embodiment, the first light emitting region PG-G that has the smallest area among the first to third light emitting regions PG-G, PG-R, and PG-B may be provided in plurality in the second region UA-P.

Two first light emitting regions may be spaced apart along the first direction DR1, and the second light emitting region PG-R and the third light emitting region PG-B may be spaced apart along the second direction DR2. The second light emitting region PG-R and the third light emitting region PG-B may be spaced apart from the first light emitting region PG-G in directions crossing the first direction DR1 and the second direction DR2, respectively.

According to an embodiment, each of the first to third light emitting regions PG-G, PG-R, and PG-B included in the second region UA-P may include at least one unit region.

For example, the first light emitting region PG-G included in the second region UA-P may include two first unit regions PP-G, the second light emitting region PG-R may include three second unit regions PP-R, and the third light emitting region PG-B may include four unit regions PP-B.

According to an embodiment, the first light emitting region PN-G of the first region UA-N may provide the same first color of light as the first light emitting region PG-G of the second region UA-P. Thus, the first unit regions PP-G included in the first light emitting region PG-G may provide the same color of light as the first light emitting region PN-G. In an embodiment, the first color may be green.

The second light emitting region PN-R of the first region UA-N may provide the same second color of light as the second light emitting region PG-R of the second region UA-P. Thus, the second unit regions PP-R included in the second light emitting region PG-R may provide the same color of light as the second light emitting region PN-R. In an embodiment, the second color may be red.

The third light emitting region PN-B of the first region UA-N may provide the same third color of light as the third light emitting region PG-B of the second region UA-P. Thus, the third unit regions PP-B in the third light emitting region PG-B may provide the same color of light as the third light emitting region PN-B. In an embodiment, the third color may be blue.

However, the embodiment is not limited thereto. The first to third colors of light are not limited to any one as long as they can be selected as a combination of three colors of light that can be mixed to generate white light.

In an embodiment, light provided from each of the light emitting regions included in the first region UA-N and the second region UA-P may be provided from a pixel PX as a result of the activation of a corresponding pixel PX among the pixels PX (see FIG. 4).

Therefore, in the disclosure below, for convenience of description, it will be described that a first pixel PU-N is activated when light is provided from the first to third light emitting regions PN-G, PN-R, and PN-B included in the first region UA-N, and that a second pixel PU-P is activated when light is provided from the first to third light emitting regions PG-G, PG-R, and PG-B included in the second region UA-P.

Referring to FIG. 10, the areas of light emitting regions providing different colors of light according to an embodiment may be different from each other. For example, the first light emitting region PN-G among the first to third light emitting regions PN-G, PN-R, and PN-B of the first region UA-N may have the smallest area. The second light emitting region PN-R may have an intermediate-sized area, and the third light emitting region PN-B may have the largest area. The first light emitting region PN-G that has the smallest area may be provided in plurality in the first region UA-N.

The area of the first light emitting region PN-G may be defined by a 1-1 side T1-GN and a 1-2 side T2-GN extended in the fourth direction DR4 and the fifth direction DR5. The area of the second light emitting region PN-R may be defined by a 1-3 side T1-RN and a 1-4 side T2-RN extended in the fourth direction DR4 and the fifth direction DR5. The area of the third light emitting region PN-B may be defined by a 1-5 side T1-BN and a 1-4 side T2-BN extended in the fourth direction DR4 and the fifth direction DR5.

The areas of the first to third light emitting regions PG-G, PG-R, and PG-B of the second region UA-P may be different from each other. According to an embodiment, the area of each of the first to third light emitting regions PG-G, PG-R, and PG-B may be determined according to an area rat of a light emitting region providing the same color of light among the first to third light emitting regions PN-G, PN-R, and PN-B of the first region UA-N.

The area of each of the first to third light emitting regions PG-G, PG-R, and PG-B of the second region UA-P may be defined as the sum of areas of unit regions included in each of the first to third light emitting regions PG-G, PG-R, and PG-B.

Since the areas of the first to third light emitting regions PG-G, PG-R, and PG-B correspond to the area ratios of the first to third light emitting regions PN-G, PN-R, and PN-B of the first region UA-N, the area of the first light emitting region PG-G may be the smallest. The second light emitting region PG-R may have an intermediate-sized area, and the third light emitting region PG-B may have the largest area. The first light emitting region PG-G that has the smallest area may be provided in plurality in the second region UA-P.

The first light emitting region PG-G may include two first unit regions PP-G. Thus, the area of one first light emitting region PG-G may be defined as the sum of the area of each of the first unit regions PP-G.

The area of each of the first unit regions PP-G may be defined by a 2-1 side T1-GP and a 2-2 side T2-GP extended in the fourth direction DR4 and the fifth direction DR5.

The second region UA-P includes two first light emitting regions, and thus, the area of first light emitting regions providing the first color of light in the second region UA-P may be defined as the sum of the area of each of four first unit regions PP-G.

The second light emitting region PG-R may include three second unit regions PP-R. Thus, the area of one second light emitting region PG-R may be defined as the sum of the area of each of the second unit regions PP-G.

The area of each of the second unit regions PP-R may be defined by a 2-3 side T1-RP and a 2-4 side T2-RP extended in the fourth direction DR4 and the fifth direction DR5.

The third light emitting region PG-B may include four third unit regions PP-B. Thus, the area of one third light emitting region PG-B may be defined as the sum of the area of each of the third unit regions PP-B.

The area of each of the third unit regions PP-B may be defined by a 2-5 side T1-BP and a 2-6 side T2-BP extended in the fourth direction DR4 and the fifth direction DR5.

According to an embodiment, among the sides of each of the first to third unit regions PP-G, PP-R, and PP-B, sides extended in the same direction may have the same width.

For example, among the sides of each of the first to third unit regions PP-G, PP-R, and PP-B, the 2-1 side T1-GP, the 2-3 side T1-RP, and the 2-5 side T1-BP extended in the fourth direction DR4 may have the same width in the fourth direction DR4.

Among the sides of each of the first to third unit regions PP-G, PP-R, and PP-B, the 2-2 side T2-GP, the 2-4 side T2-RP, and the 2-6 side T2-BP extended in the fifth direction DR5 may have the same width in the fifth direction DR5. The first to third unit regions PP-G, PP-R, and PP-B may have the same area.

The cross-sections of the display panel DP illustrated in FIG. 11 and FIG. 12 may correspond to the stacking structure of the display panel DP described with reference to FIG. 3A, and redundant descriptions will be omitted.

As illustrated in FIG. 11 and FIG. 12, the display module DM (see FIG. 2) may include the display panel DP, the input sensor ISL, the light blocking layer PVL, and the optical member POL in the active region AA. The display panel DP may include the base layer BL, the circuit element layer DP-CL, the display element layer DP-OLED, and the thin film encapsulation layer TFL.

The circuit element layer DP-CL is disposed on the base layer BL, and the display element layer DP-OLED is disposed on the circuit element layer DP-CL. The light emitting device OLED included in the display element layer DP-OLED may be connected to a transistor (omitted) included in the circuit element layer DP-CL. The thin film encapsulation layer TFL may be disposed on the display element layer DP-OLED and protect the light emitting device OLED.

The light emitting device OLED may include a first electrode AE disposed on the circuit element layer DP-CL, a second electrode CE disposed on the first electrode AE, and a light emitting layer EML disposed between the first electrode AE and the second electrode CE. A hole control layer disposed between the first electrode AE and the light emitting layer EML may be further included. The hole control layer includes a hole transport layer, and may further include a hole injection layer. In addition, an electron control layer disposed between the light emitting layer EML and the second electrode CE may be further included. The electron control layer includes an electron transport layer, and may further include an electron injection layer.

The first electrode AE and the light emitting layer EML may be provided to each of a plurality of light emitting devices, and the second electrode CE may be formed as one pattern and commonly provided to the plurality of light emitting devices. However, the embodiment is not limited thereto. The light emitting layer EML may be formed as one pattern and commonly provided to the plurality of light emitting devices.

The display element layer DP-OLED may includes a pixel definition layer PDL. The pixel definition layer PDL may be disposed on the circuit element layer DP-CL. On the pixel definition layer PDL, a display opening PD-OP that exposes at least a portion of the first electrode AE may be defined. The display opening PD-OP may be provided in plurality so as to correspond to each of first electrodes provided in plurality for each light emitting device.

In the present disclosure, a ‘light emitting region’ may be substantially defined by the display opening PD-OP defined on the pixel definition layer PDL. Thus, the difference in areas between light emitting regions defined in each of the first region UA-P and the second region UA-P described above with reference to FIG. 10 may be provided according to the difference in areas between display openings of the pixel definition layer PDL.

As illustrated in FIG. 11, the plurality of display openings PD-OP included in the first region UA-N may define the first to third light emitting regions N-G, PN-R, and PN-B having different areas. Gaps between the first to third emission PN-G, PN-R, and PN-B may be defined as a non-light emitting region NPXA.

As illustrated in FIG. 12, the plurality of display openings PD-OP included in the second region UA-P may define the first to third light emitting regions PG-G, PG-R, and PG-B having different areas.

As described with reference to FIG. 10, each of the first to third light emitting regions PG-G, PG-R, and PG-B includes the first to third unit regions PP-G, PP-R, and PP-B, and first to third unit regions PP-G, PP-R, and PP-B extended in the same direction may have the same width.

The pixel definition layer PDL according to an embodiment may include first partitioning patterns PDP-G, PDP-R, and PDP-B. The first partitioning patterns PDP-G, PDP-R, and PDP-B may partition the first to third light emitting regions PG-G, PG-R, and PG-B into the first to third unit regions PP-G, PP-R, and PP-B.

For example, the first light emitting region PG-G may be partitioned into the first unit regions PP-G by a 1-1 partitioning pattern PDP-G, the second light emitting region PG-R may be partitioned into the second unit regions PP-R by a 1-2 partitioning pattern PDP-R, and the third light emitting region PG-B may be partitioned into the third unit regions PP-B by a 1-3 partitioning pattern PDP-B.

The 1-1 partitioning pattern PDP-G is disposed on the first electrode AE exposed by a display opening PD-OP defining the first light emitting region PG-G. The 1-2 partitioning pattern PDP-R is disposed on the first electrode AE exposed by a display opening PD-OP defining the second light emitting region PG-R. The 1-3 partitioning pattern PDP-B is disposed on the first electrode AE exposed by a display opening PD-OP defining the third light emitting region PG-B.

The first partitioning patterns PDP-G, PDP-R, and PDP-B are components substantially integral with the pixel definition layer PDL, and are formed by patterning one layer. However, for convenience of description, a pixel definition layer PDL disposed on the first electrode AE in the second region UA-P will be described as the first partitioning patterns PDP-G, PDP-R, and PDP-B.

As described with reference to FIG. 10, although the numbers of corresponding first to third unit regions PP-G, PP-R, and PP-B in the first to third light emitting regions PG-G, PG-R, and PG-B are different from each other, each of the first to third unit regions PP-G, PP-R, and PP-B extended in the same direction has the same width, so that the first partitioning patterns PDP-G, PDP-R, and PDP-B adjacent to a side surface of a pixel definition layer PDL defining the display opening PD-OP may have the same width therebetween in the same direction.

In each of the first electrodes AE included in the light emitting devices OLED, a portion covered by corresponding first partitioning patterns PDP-G, PDP-R, and PDP-B may be defined as the non-light emitting region NPXA.

Thus, the active region AA of the display module DM may include the first region UA-N with a relatively large amount of light provided from the light emitting devices OLED and the second region UA-P with a relatively small amount of light compared to the first region UA-N.

In the present disclosure, any one among the first to third light emitting regions PN-G, PN-R, and PN-B included in the first region UA-N may be defined as a ‘normal region’, and any one among the first to third light emitting regions PG-G, PG-R, and PG-B included in the second region UA-P may be defined a ‘private region.’

The input sensor ISL may be directly disposed on the thin film encapsulation layer TFL. The first sensing insulation layer TIL1 is disposed on the thin film encapsulation layer TFL, and the first conductive layer TML1 is disposed on the first sensing insulation layer TIL1. The second sensing insulation layer TIL2 is disposed on the first sensing insulation layer TIL1 and covers the first conductive layer TML1, and the second conductive layer TML2 is disposed on the second sensing insulation layer TIL2. The third conductive layer TML3 is disposed on the second sensing insulation layer TIL2 and covers the second conductive layer TML2.

The mesh lines (see FIG. 8) included in the second conductive layer TML2 define the mesh openings MSL-OP. The mesh openings MSL-OP may overlap corresponding light emitting regions. Thus, even when the conductive layers TML1 and TML2 are directly disposed on the display panel DP, interference with light provided from the light emitting devices OLED may be minimized.

The light blocking layer PVL may be disposed on the input sensor ISL. The light blocking layer PVL may include the light blocking pattern BM and the passivation layer PVX.

The light blocking pattern BM may have a predetermined color. For example, the light blocking pattern BM be black. The light blocking pattern BM is not limited to any one material as long as it is capable of absorbing light.

The light blocking pattern BM may overlap the pixel definition layer PDL. Specifically, the light blocking pattern BM may overlap a pixel definition layer PDL disposed in the first region UA-N, and may overlap a pixel definition layer PDL disposed in the second region UA-P. The light blocking pattern BM according to an embodiment may overlap the first partitioning patterns PDP-G, PDP-R, and PDP-B in the second region UA-P.

Accordingly, the viewing angle of light provided from the first to third light emitting regions PG-G, PG-R, and PG-B of the second region UA-P may be provided to a user as a narrower viewing angle than the viewing angle of light provided from the first to third light emitting regions PN-G, PN-R, and PN-B of the first region UA-B by the light blocking pattern BM.

The passivation layer PVX may cover the light blocking pattern BM. The passivation layer PVX may provide a flat surface to facilitate the bonding of components disposed on the passivation layer PVX. The passivation layer PVX may include an organic material.

The passivation layer PVX is illustrated as being disposed on the entire surface of the active region AA, but the embodiment is not limited thereto. The passivation layer PVX may be disposed only on the non-light emitting region NPXA by covering the light blocking pattern BM, and may be patterned not to overlap light emitting regions, but is not limited to any one embodiment.

The display module DM according to an embodiment may operate in two modes. A ‘first operation mode’ may be defined as a state in which the first pixel PU-N and the second pixel PU-P included in the active region AA of the display module DM are activated, and a ‘second operation mode’ may be defined as a state in which the first pixel PU-N is inactivated and only the second pixel PU-P is activated.

Thus, when in the second operation mode, the area of light emitting regions activated is relatively reduced compared to when in the first operation mode, so that an image of a low resolution may be provided to a user.

The first operation mode may generally correspond to a mode in which the display device EA is operated. The second operation mode may be used when the display device EA is used for a specific purpose. For example, the second operation mode is a private mode, and when operated in the second operation mode, the active region AA is not visually recognized by people adjacent to the display device EA, but is visually recognized only by a user, so that it is possible to prevent the leakage of personal information.

When a user views the display device EA from the side, some regions of the first to third light emitting regions PG-G, PG-R, and PG-B disposed in the second region UA-P are obscured by the first partitioning patterns PDP-G, PDP-R, and PDP-B. Unlike the embodiments described herein, when the respective areas of the first to third unit regions PP-G, PP-R, and PP-B of each of the first to third light emitting regions PG-G, PG-R, and PG-B having a narrow viewing angle are different from each other, a color shift phenomenon may occur.

For example, it is assumed that a first light emitting region has a maximum light emitting area ratio of 100:0 on the basis of the width of 10a×10b, and a second light emitting region has a maximum light emitting area ratio of 25:0 on the basis of the width of 5a×5b.

When a user views the display device EA from the side, and when it is assumed that an area obscured by a first partitioning pattern corresponding to the first light emitting region is 1a×10b, the ratio of a light emitting area to a light blocking area may be 90:10, resulting in achieving a light emitting area ratio of 90%.

Under the same conditions, when it is assumed that an area obscured by a first partitioning pattern corresponding to the second light emitting region is lax 5b, the ratio of a light emitting area to a light blocking area may be 20:5, resulting in achieving a light emitting area ratio of 80%.

Thus, when the respective areas of the first to third unit regions PP-G, PP-R, and PP-B are different from each other, a luminance ratio may decrease according to an angle at that a user views the display device EA, so that a color shift phenomenon may occur.

According to an embodiment, each of the first to third unit regions PP-G, PP-R, and PP-B activated in the second operation mode has the same width in one direction, so that even when light provided from the first to third unit regions PP-G, PP-R, and PP-B is obscured by the first partitioning patterns PDP-G, PDP-R, and PDP-B, the same image may be provided to a user without color shift at a specific angle. Accordingly, the display apparatus EA with improved reliability may be provided.

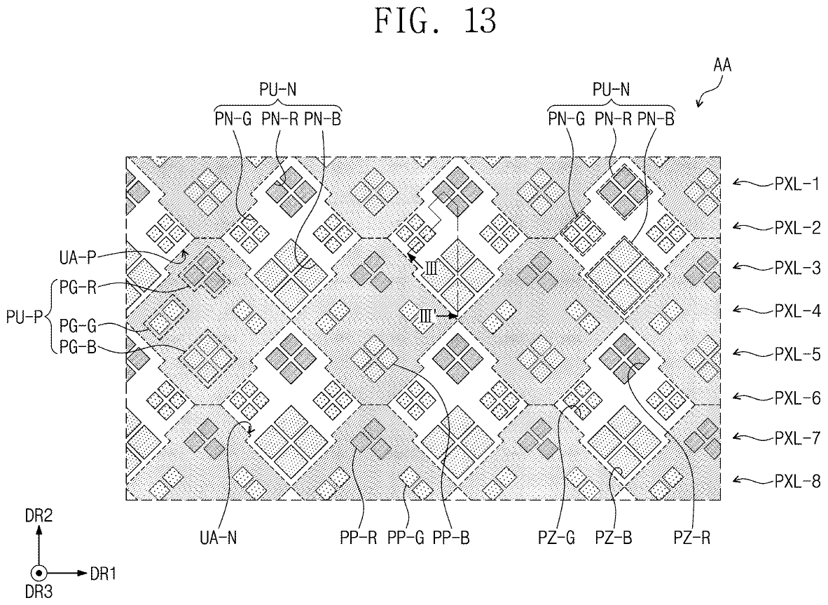

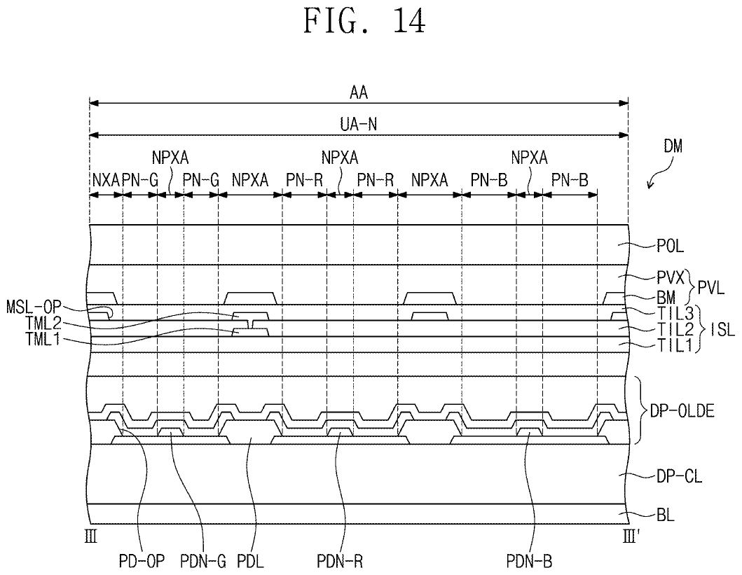

FIG. 13 is a plan view of an active region according to an embodiment. FIG. 14 is a cross-sectional view of a display module taken along of FIG. 13. The same/similar reference numerals are used for the same/similar components as those described with reference to FIG. 1 to FIG. 12, and redundant descriptions thereof will be omitted.

In FIG. 13 and FIG. 14, descriptions of the second pixel PU-P included in the second region UA-P, that is, the plurality of the first to third light emitting regions PG-G, PG-R, and PG-B included in the second region UA-P, and of the first to third unit regions PP-G, PP-R, and PP-B are the same as those described with reference to FIG. 1 to FIG. 12, and the first to third light emitting regions PG-G, PG-R, and PG-B disposed in the first region PU-N will be mainly described.

Referring to FIG. 13 and FIG. 14, an active region AA of a display module DM-A according to an embodiment may include a first region UA-N and a second region UA-P.

In the embodiment, the first region UA-N may include a plurality of first to third light emitting regions PN-G, PN-R, and PN-B. In an embodiment, a first light emitting region PN-G that has the smallest area among the first to third light emitting regions PN-G, PN-R, and PN-B may be provided in plurality in the first region UA-N.

Two first light emitting regions may be spaced apart along the first direction DR1, and a second light emitting region PN-R and a third light emitting region PN-B may be spaced apart along the second direction DR2. The second light emitting region PN-R and the third light emitting region PN-B may be spaced apart from the first light emitting region PN-G in directions crossing the first direction DR1 and the second direction DR2, respectively.

According to an embodiment, each of the first to third light emitting regions PN-G, PN-R, and PN-B included in the first region UA-N may include at least one sub-unit region.

In an embodiment, the number of first sub-unit regions PZ-G included in the first light emitting region PN-G, the number of second sub-unit regions PZ-R included in the second light emitting region PN-R, and the number of third sub-unit regions PZ-B included in the third light emitting region PN-B may be the same as each other. For example, each of the first to third light emitting regions PN-G, PN-R, and PN-B may include four sub-unit regions. As two first light emitting regions PN-G are provided in the first region UA-N, the number of the first sub-unit regions PZ-G may be the largest in the first region UA-N.

The respective widths of the first to third sub-unit regions PZ-G, PZ-R, and PZ-B extended in the same direction may be different from each other. The area of each of the first to third light emitting regions PN-G, PN-R, and PN-B may be defined as the sum of areas of sub-unit regions included therein.

The second region UA-P may include a plurality of first to third light emitting regions PG-G, PG-R, and PG-B. In an embodiment, the first light emitting region PG-G that has the smallest area among the first to third light emitting regions PG-G, PG-R, and PG-B may be provided in plurality in the second region UA-P.

Two first light emitting regions may be spaced apart along the first direction DR1, and the second light emitting region PG-R and the third light emitting region PG-B may be spaced apart along the second direction DR2. The second light emitting region PG-R and the third light emitting region PG-B may be spaced apart from the first light emitting region PG-G in directions crossing the first direction DR1 and the second direction DR2, respectively.

According to an embodiment, each of the first to third light emitting regions PG-G, PG-R, and PG-B included in the second region UA-P may include at least one unit region.

For example, the first light emitting region PG-G included in the second region UA-P may include two first unit regions PP-G, the second light emitting region PG-R may include three second unit regions PP-R, and the third light emitting region PG-B may include four unit regions PP-B.

A cross-sectional view with respect to the second region UA-P may correspond to the cross-sectional view described with reference to FIG. 12, and a cross-sectional view of the first region UA-N of the display module DM-A of the embodiment will be described.

As illustrated in FIG. 14, the pixel definition layer PDL disposed in the first region UA-N in the embodiment may include second partitioning patterns PDN-G, PDN-R, and PDN-B. The second partitioning patterns PDN-G, PDN-R, and PDN-B may partition the first to third light emitting regions PN-G, PN-R, and PN-B into the first to third sub-unit regions PZ-G, PZ-R, and PZ-B.

For example, the first light emitting region PN-G may be partitioned into the first sub-unit regions PZ-G by a 2-1 partitioning pattern PDN-G, the second light emitting region PN-R may be partitioned into the second sub-unit regions PZ-R by a 2-2 partitioning pattern PDN-R, and the third light emitting region PN-B may be partitioned into the third sub-unit regions PZ-B by a 2-3 partitioning pattern PDN-B.

The 2-1 partitioning pattern PDN-G is disposed on the first electrode AE exposed by a display opening PD-OP defining the first light emitting region PN-G. The 2-2 partitioning pattern PDN-R is disposed on the first electrode AE exposed by a display opening PD-OP defining the second light emitting region PN-R. The 2-3 partitioning pattern PDN-B is disposed on the first electrode AE exposed by a display opening PD-OP defining the third light emitting region PN-B.

The second partitioning patterns PDN-G, PDN-R, and PDN-B are components substantially integral with the pixel definition layer PDL, and are formed by patterning one layer. However, for convenience of description, a pixel definition layer PDL disposed on the first electrode AE in the first region UA-N will be described as the second partitioning patterns PDN-G, PDN-R, and PDN-B.

In the embodiment, the light blocking pattern BM may overlap only the pixel definition layer PDL except for the second partitioning patterns PDN-G, PDN-R, and PDN-B of the pixel definition layer PDL in the first region UA-N. Accordingly, even when the first to third light emitting regions PN-G, PN-R, and PN-B are partitioned into corresponding second partitioning patterns PDN-G, PDN-R, and PDN-B in the first region UA-N, the light blocking pattern BM is disposed on the second partitioning patterns PDN-G, PDN-R, and PDN-B, so that the viewing angle of the first region UA-N may not be reduced.

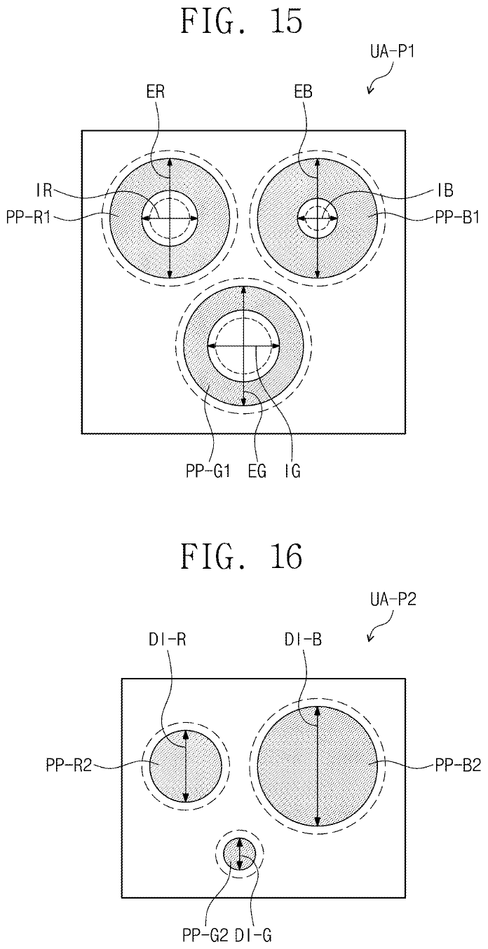

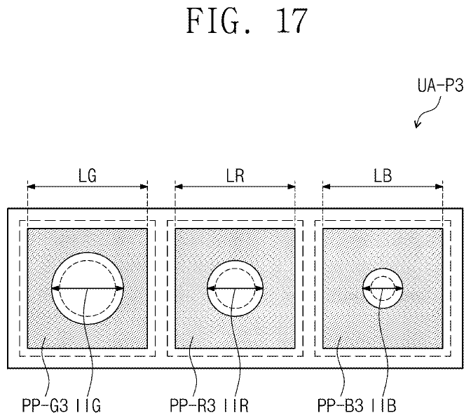

FIG. 15 is a plan view of a unit region according to an embodiment. FIG. 16 is a plan view of a unit region according to an embodiment. FIG. 17 is a plan view of a unit region according to an embodiment. The same/similar reference numerals are used for the same/similar components as those described with reference to FIG. 1 to FIG. 12, and redundant descriptions thereof will be omitted for ease in explanation of these figures.

The description of light emitting regions to be given with reference to FIG. 15 to FIG. 17 may be applied to the light emitting regions included in the second region UA-P described with reference to FIG. 1 to FIG. 12. In addition, the shape of each of the light emitting regions to be described with reference to FIG. 15 to FIG. 17 may be defined by the display openings PD-OP of the pixel definition layer PDL described with reference to FIG. 12.

Referring to FIG. 15, a second region UA-P1 according to an embodiment may include first to third light emitting regions PP-G1, PP-R1, and PP-B1. Each of the first to third light emitting regions PP-G1, PP-R1, and PP-B1 may have a donut shape.

The light emitting areas of the first to third light emitting regions PP-G1, PP-R1, and PP-B1 may be different from each other. The light emitting area of each of the first to third light emitting regions PP-G1, PP-R1, and PP-B1 may be defined by the area of a ring shape obtained after subtracting the inner diameter thereof from the outer diameter thereof.

According to the embodiment, outer diameters EG, ER, and EB of the first to third light emitting regions PP-G1, PP-R1, and PP-B1 are the same as each other, and inner diameters IG, IR, and D3 of the first to third light emitting regions PP-G1, PP-R1, and PP-B1 may be different from each other.

The inner diameter IG of the first light emitting region PP-G1 may be the largest, and the inner diameter D3 of the third light emitting region PP-B1 may be the smallest. Accordingly, the light emitting area may increase going from the first light emitting region PP-G1 to the third light emitting region PP-B1.

Referring to FIG. 16, a second region UA-P2 according to an embodiment may include first to third light emitting regions PP-G2, PP-R2, and PP-B2. Each of the first to third light emitting regions PP-G2, PP-R2, and PP-B2 may have a circular shape.

The light emitting areas of the first to third light emitting regions PP-G2, PP-R2, and PP-B2 may be different from each other.

In the embodiment, outer diameters DI-G, DI-R, and DI-B of the first to third light emitting regions PP-G2, PP-R2, and PP-B2 may be different from each other. For example, the outer diameter DI-G of the first light emitting region PP-G2 may be the smallest, and the outer diameter DI-B of the third light emitting region PP-B2 may be the largest. Accordingly, the light emitting area may increase going from the first light emitting region PP-G1 to the third light emitting region PP-B1.

In the embodiments described with reference to FIG. 9 to FIG. 14, the light emitting regions are illustratively described as light emitting regions of a quadrangular shape, but are not limited thereto. The shape of the first to third light emitting regions PN-G, PN-R, and PN-B of the first pixel PU-N and the shape of the first to third light emitting regions PG-G, PG-R, and PG-B included in the second pixel PU-P described with reference to FIG. 9 may be circular as described with reference to FIG. 16.

Thus, the properties of the first pixel PU-N and the second pixel PU-P may be applied even when a light emitting region is defined to have a circular shape, and are not limited to any one embodiment.

Referring to FIG. 17, a second region UA-P3 according to an embodiment may include first to third light emitting regions PP-G3, PP-R3, and PP-B3. The boundary of each of the first to third light emitting regions PP-G3, PP-R3, and PP-B3 may have a quadrangular shape.

The light emitting areas of the first to third light emitting regions PP-G3, PP-R3, and PP-B3 may be different from each other. The light emitting area of each of the first to third light emitting regions PP-G3, PP-R3, and PP-B3 may be defined by subtracting the area of a circle defined thereinside from the area defined by outer widths thereof.

In the same direction, widths LG, LR, and LB of the first to third light emitting regions PP-G3, PP-R3, and PP-B3 may be the same as each other. In addition, inner diameters IIG, IIR, and IIB of the first to third light emitting regions PP-G3, PP-R3, and PP-B3 may be different from each other. The inner diameter IIG of the first light emitting region PP-G3 may be the largest, and the inner diameter IIB of the third light emitting region PP-B3 may be the smallest. Accordingly, the light emitting area may increase going from the first light emitting region PP-G3 to the third light emitting region PP-B3.

As in the embodiments described with reference to FIG. 15 to FIG. 17, the embodiments described with reference to FIG. 9 to FIG. 14 may be applied to a pixel form with an adjustable light emitting area defined by the difference in an external shape and an internal shape since light emitting regions have the same external shape and different internal shapes on a plane. However, the inventive concept is not limited to any one embodiment.

According to an inventive concept consistent with one or more embodiments described hereinabove, each of light emitting regions activated in a private operation mode has the same width in one direction, so that even when light provided from the light emitting regions is obscured by partitioning patterns, the same image may be provided to a user without color shift at a specific angle. Accordingly, a display device with improved reliability may be provided.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display device comprising:
a display panel that includes a first region and a second region, each of which includes first to third light emitting regions and a non-light emitting region, and that includes first to third light emitting elements that provide different colors of light to corresponding first to third light emitting regions;
at least one insulation layer disposed on the display panel;
a light blocking pattern disposed on the at least one insulation layer, and that overlaps the non-light emitting region; and
a passivation layer that covers the light blocking pattern,
wherein:
each of the first to third light emitting regions of the second region includes a plurality of unit regions; and
a first width of each of the unit regions in one direction is equal to each of the unit regions and a second width of each of the first to third light emitting regions of the first region in one direction is smaller than the first width.

2. The display device of claim 1, wherein a number of the unit regions included in the respective first to third light emitting regions of the second region are different from each other.

3. The display device of claim 2, wherein the number of the unit regions are proportional to area sizes of the first to third light emitting regions of the first region.

4. The display device of claim 3, wherein among the first to third light emitting regions of each of the first and second regions, green light is provided to the first light emitting region, red light is provided to the second light emitting region, and blue light is provided to the third light emitting region, and
in the second region, a number of the unit regions included in the third light emitting region is the greatest, and in the second region, a number of the unit regions included in the first light emitting region is the smallest.

5. The display device of claim 3, wherein the first light emitting region of each of the first region and the second region is provided in plurality.

6. The display device of claim 1, wherein:
each of the first to third light emitting regions of the first region comprises a plurality of sub-unit regions, and
the sub-unit regions have respective widths different from each other in the one direction.

7. The display device of claim 6, wherein:
a number of the sub-unit regions included in the first light emitting region of the first region is different from a number of the unit regions included in the first light emitting region of the second region; and
a number of the sub-unit regions included in the second light emitting region of the first region is different from a number of the unit regions included in the second light emitting region of the second region.

8. The display device of claim 1, wherein:
each of the first to third light emitting elements comprises a first electrode, a second electrode disposed on the first electrode, and a light emitting layer disposed between the first electrode and the second electrode; and
the display panel comprises a pixel definition layer including a plurality of openings that expose at least a portion of the first electrodes, wherein the respective areas of the openings define the first to third light emitting regions.

9. The display device of claim 8, wherein:
the pixel definition layer comprises a first partitioning pattern that overlaps the second region and disposed on the first electrodes exposed by the openings; and
the unit regions of the second region are defined by the areas of the openings partitioned by the first partitioning pattern.

10. The display device of claim 9, wherein:
each of the first to third light emitting regions of the first region comprises a plurality of sub-unit regions;
the pixel definition layer comprises a second partitioning pattern overlapping the first region and disposed on the first electrodes exposed by the openings; and
the unit regions of the first region are defined by the areas of the openings partitioned by the second partitioning pattern.

11. The display device of claim 10, wherein the light blocking pattern overlaps the pixel definition layer except for the second partitioning pattern of the pixel definition layer.

12. The display device of claim 1, wherein the display panel further comprises:
a thin film encapsulation layer that covers the first to third light emitting elements and that includes a plurality of inorganic layers and an organic layer disposed between the inorganic layers; and
an input sensor disposed on the thin film encapsulation layer and including a plurality of sensing insulation layers and conductive layers disposed between the sensing insulation layers, wherein the at least one insulation layer corresponds to a sensing insulation layer disposed on the uppermost portion of the sensing insulation layers.

13. The display device of claim 1, further comprising an optical member disposed on the passivation layer, and that includes at least one of a reflection prevention film, a polarizing film, or a gray filter.

14. The display device of claim 1, further comprising a light filter member disposed on the passivation layer and that includes color filters that overlap corresponding first to third light emitting regions.

15. The display device of claim 1, wherein:
each of the unit regions of the second region has a donut shape;
an outer diameter that defines a boundary of each of the unit regions corresponds to a width of each of the unit regions in one direction; and
respective inner diameters of the unit regions included in different first to third light emitting regions of the second region are different from each other.

16. The display device of claim 1, wherein each of the unit regions of the second region has a quadrangular shape that defines a boundary, and respective inner diameters of the unit regions included in different first to third light emitting regions of the second region are different from each other.

17. The display device of claim 1, wherein the display panel activates the first to third light emitting elements of the first region and the first to third light emitting elements of the second region in a first operation mode; and
inactivates the first to third light emitting elements of the first region and activates the first to third light emitting elements of the second region in a second operation mode.

18. A display device comprising:
a display panel including a pixel definition layer on which openings defining a normal light emitting region and a private light emitting region spaced apart from the normal light emitting region are defined, and light emitting elements that overlaps a corresponding normal light emitting region and a corresponding private light emitting region and configured to provide the same color of light;
an insulation layer disposed on the display panel;
a light blocking pattern disposed on the insulation layer; and
a passivation layer that covers the light blocking pattern, wherein each of the light emitting elements includes a first electrode, at least a portion of that is exposed by corresponding openings, a second electrode disposed on the first electrode, and a light emitting layer disposed between the first electrode and the second electrode, and
the pixel definition layer includes a partitioning pattern disposed on the first electrode exposed by an opening that overlaps the private light emitting region, and partitioning the private light emitting region into a plurality of unit regions.

19. The display device of claim 18, wherein each of the unit regions has the same width in one direction.

20. The display device of claim 19, wherein the width of each of the unit regions is smaller than a width of the normal light emitting region in the one direction.

21. The display device of claim 18, wherein the light blocking pattern overlaps the partitioning pattern.

22. The display device of claim 18, wherein the display panel is configured to activate a light emitting element that overlaps the normal light emitting region and to activate a light emitting element that overlaps the private light emitting region in a first operation mode, and
wherein the display panel is configured to activate the light emitting element that overlaps the normal light emitting region and the light emitting element that overlaps the private light emitting region in a second operation mode.

23. The display device of claim 18, wherein the unit regions are defined by the areas of the openings partitioned by the partitioning pattern.
